(19) United States
(12) Patent Application Publication
(10) Pub. No.: US 2025/0282611 A1
(43) Pub. Date: Sep. 11, 2025

(54) MICRO-DIFFERENTIAL PRESSURE SENSOR, PACKAGING STRUCTURE, TESTING METHOD AND ELECTRONIC DEVICE

(71) Applicant: Memsensing Microsystems (Suzhou, China) Co., Ltd., Suzhou (CN)

(72) Inventors: Min ZHANG, Suzhou (CN); Gang LI, Suzhou (CN); Jiaxin MEI, Suzhou (CN)

(73) Assignee: Memsensing Microsystems (Suzhou, China) Co., Ltd., Suzhou (CN)

(21) Appl. No.: 18/892,603

(22) Filed: Sep. 23, 2024

(30) Foreign Application Priority Data
Mar. 7, 2024 (CN) 202410258763.X

(51) Int. Cl. B81B 7/00; B81C 99/00; G01L 9/00

(52) U.S. Cl. CPC B81B 7/007; B81C 99/0035; G01L 9/0072; B81B 2203/0127; B81B 2203/0315; B81B 2203/0353; B81B 2203/04; B81B 2207/07; B81B 2207/091

(57) ABSTRACT

Disclosed a micro-differential pressure sensor, a package structure, a test method, and an electronic device. The micro-differential pressure sensor comprises a MEMS chip, the MEMS chip comprises a substrate, a diaphragm, and a back-pole plate set in a laminated manner, the substrate having a back cavity which passes through in the thickness direction thereof, the back-pole plate comprises a first electrode region and a second electrode region isolated from each other, the first electrode region forming a first electrode, the second electrode region forming a second electrode, and the diaphragm forming a third electrode, the first electrode and the third electrode form a first capacitor, the second electrode and the third electrode form a second capacitor.

### RELATED APPLICATIONS

This application is a Paris Convention, which claims the benefit of priority of China Patent Application No. 202410258763.X, filed on Mar. 7, 2024. The contents of the above application is all incorporated by reference as if fully set forth herein in its entirety.

### FIELD AND BACKGROUND OF THE INVENTION

The present invention relates to the technical field of micro-differential pressure sensors, and more specifically, to a micro-differential pressure sensor, a packaging structure, a testing method and an electronic device.

In the micro-differential pressure products market, micro-differential pressure products based on MEMS (Micro-Electro-Mechanical System) chips manufactured by MEMS are increasingly being accepted in the market. MEMS chips mainly comprise of diaphragm and back-pole plate, and there is a gap between the diaphragm and the back-pole plate. A change in air pressure causes deformation of the diaphragm and a change in the capacitance value between the diaphragm and the back-pole plate, which is converted to an electrical signal output. In order to confirm whether the MEMS chip micro-differential pressure product meets the preset requirements, the airflow test method is commonly employed before being shipped from the factory.

However, with the increase in market capacity and the surge in demand, the testing capacity of MEMS chip micro-differential pressure products is limited, and adding air flow testing requires a lot of equipment and costs.

### SUMMARY OF THE INVENTION

The present invention aims to solve at least one of the technical problems existing in the prior art and provide a micro-differential pressure sensor, a packaging structure, a testing method and an electronic device.

The purpose of the present invention is achieved by the following technical solutions:

According to a first aspect of the present invention, a micro-differential pressure sensor is provided. The micro-differential pressure sensor comprises a MEMS chip, the MEMS chip comprises a substrate, a diaphragm, and a back-pole plate set in a laminated manner, the substrate having a back cavity which passes through in the thickness direction thereof, the back-pole plate comprises a first electrode region and a second electrode region isolated from each other, the first electrode region forming a first electrode, the second electrode region forming a second electrode, and the diaphragm forming a third electrode, the first electrode and the third electrode form a first capacitor, and the second electrode and the third electrode form a second capacitor;
the MEMS chip comprises a first electrical connection end, a second electrical connection end, and a third electrical connection end;
wherein the first electrical connection end is electrically connected to the first electrode, the first electrical connection end being configured to provide a voltage excitation signal or a high voltage signal; the second electrical connection end is electrically connected to the second electrode, the second electrical connection end being configured to provide a ground signal; the third electrical connection end is electrically connected to the third electrode, and the third electrical connection end serves as a signal output terminal of the MEMS chip to output a change amount of the second capacitor, so as to determine whether the MEMS chip is in a degraded state according to a first preset threshold.

According to a second aspect of the present invention, a micro-differential pressure sensor packaging structure is provided. The packaging structure comprises a baseplate, a housing, and the above-mentioned micro-differential pressure sensor;
the baseplate comprises a first surface and a second surface positioned opposite to each other, the first surface of the baseplate is fixedly connected to the housing to form a cavity, the MEMS chip is fixedly connected to the first surface and disposed in the cavity, a first through hole is formed on the baseplate, and the MEMS chip covers the first through hole;
the first surface comprises a first signal terminal, a ground terminal, and a second signal terminal spaced apart;
wherein the first signal terminal is configured to be electrically

connected to the first electrical connection end, the ground terminal is configured to be electrically connected to the second electrical connection end, and the second signal terminal is configured to be electrically connected to the third electrical connection end.

According to a third aspect of the present invention, a testing method is provided, for testing the above-mentioned micro-differential pressure sensor, or for testing the above-mentioned packaging structure, wherein the testing method comprises the steps of:

Applying a voltage excitation signal to the first electrode, to cause a change in the capacitance value of the first capacitor based on the change in the voltage excitation signal, and drive the diaphragm to perform adsorption motion from an equilibrium position toward the side close to the back-pole plate in an adsorption motion; or, applying a high voltage signal to the first electrode, cause the diaphragm to deform based on the high voltage signal, and then gradually reduce the high voltage signal, so as to cause the diaphragm to return from the deformed position to the equilibrium position;

Obtaining the change amount of the second capacitor, and determine whether the change amount of the second capacitor reaches the first preset threshold. If so, determine the MEMS chip to be in a non-degraded state; otherwise, determine the MEMS chip to be in a degraded state.

According to a fourth aspect of the present invention, an electronic device is provided. The electronic device comprises the above-mentioned packaging structure.

Embodiments of the present invention provide a micro-differential pressure sensor, a packaging structure, a test method, and an electronic device that can replace the existing art of the airflow test method for the MEMS chip micro-differential pressure products, and have good test stability as well as high test efficiency,
wherein, the micro-differential pressure sensor comprises a MEMS chip, the MEMS chip comprises a substrate, a diaphragm, and a back-pole plate set in a laminated manner, the substrate having a back cavity which passes through in the thickness direction thereof, the back-pole plate comprises a first electrode region and a second electrode region isolated from each other, the first electrode region forming a first electrode, the second electrode region forming a second electrode, and the diaphragm forming a third electrode, the first electrode and the third electrode form a first capacitor, and the second electrode and the third electrode form a second capacitor. By applying a voltage excitation signal or a high voltage signal or the like to the first electrode through the first electrical connection end, the diaphragm is driven to deform to change the spacing between the diaphragm and the back-pole plate to simulate the airflow test method; and then output the sensed signal through the third electrical connection end. The measured change amount of the second capacitor is used to determine whether the MEMS chip is in the degraded state according to the first preset threshold.

### BRIEF DESCRIPTION OF THE SEVERAL VIEWS OF THE DRAWING(S)

To describe technical solutions in embodiments of this application more clearly, the following briefly introduces the accompanying drawings for describing the embodiments. It is clear that the accompanying drawings in the following descriptions show merely some embodiments of this application, and a person skilled in the art may still derive other drawings from these accompanying drawings without creative efforts.

FIG. 1 is a schematic diagram of a structure of a MEMS chip in a micro-differential pressure sensor, according to an embodiment of the present invention;

FIG. 2A is a schematic diagram of a circuit structure of a MEMS chip in a micro-differential pressure sensor, according to a first embodiment of the present invention;

FIG. 2B is a schematic diagram of a circuit structure in connecting the MEMS chip and the ASIC chip in the micro-differential pressure sensor, according to a second embodiment of the present invention;

FIG. 3 is a schematic diagram of a side view structure of a micro-differential pressure sensor packaging structure, according to an embodiment of the present invention;

FIG. 4 is a schematic diagram of a top view structure of a micro-differential pressure sensor packaging structure, according to a first embodiment of the present invention;

FIG. 5 is a schematic diagram of a top view structure of a micro-differential pressure sensor packaging structure, according to a second embodiment of the present invention;

FIG. 6 is a schematic diagram of an elevation view structure of a micro-differential pressure sensor packaging structure, according to a first embodiment of the present invention;

FIG. 7 is a schematic diagram of an elevation view structure of a micro-differential pressure sensor packaging structure, according to a second embodiment of the present invention;

FIG. 8 is a schematic diagram of an elevation view structure of a micro-differential pressure sensor packaging structure, according to a third embodiment of the present invention;

FIG. 9 is a schematic diagram of an elevation view structure of a micro-differential pressure sensor packaging structure, according to a fourth embodiment of the present invention;

FIG. 10 is a schematic diagram of an elevation view structure of a micro-differential pressure sensor packaging structure, according to a fifth embodiment of the present invention;

FIG. 11 is a schematic diagram of an elevation view structure of a micro-differential pressure sensor packaging structure, according to a sixth embodiment of the present invention;

FIG. 12 is a schematic diagram of an elevation view structure of a micro-differential pressure sensor packaging structure, according to a seventh embodiment of the present invention;

FIG. 13 is a schematic diagram of a circuit structure of a micro-differential pressure sensor packaging structure, according to an embodiment of the present invention.

The meanings of the reference numbers are as follows:

40-MEMS chip; 410-diaphragm; 420-back-pole plate; 430-substrate; 431-back cavity; 421-first electrode region; 422-second electrode region; 401-first electrical connection end; 402-second electrical connection end; 403-third electrical connection end; 510-first support body; 520-second support body; 30-ASIC chip;

1000-packaging structure; 10-housing; 20-baseplate; 20A-first surface; 20B-second surface; 101-cavity; 60-first through hole; 110-first air permeable structure; 201-first signal terminal; 202-ground terminal; 203-second signal terminal;

301-first pad; 302-ground pad; 303-second pad; 701-isolation band;

C1-first capacitor; C2-second capacitor.

### DESCRIPTION OF SPECIFIC EMBODIMENTS OF THE INVENTION

The above description is only an overview of the technical solution of the present invention, in order to be able to more clearly understand the technical means of the present invention, and can be implemented in accordance with the contents of the specification, and in order to make the above and other purposes, features and advantages of the present invention can be more obvious and easy to understand, the following specially cites some embodiments and with the accompanying drawings, the following is described in detail.

In the description of the present invention, it should be noted that unless otherwise specified and limited, terms such as “set,” “connect,” and “attach” should be broadly interpreted. For example, it can be a fixed connection or a detachable connection, or even an integral connection. It can be a mechanical connection, an electrical connection, or a communicative connection. It can be directly connected or indirectly connected through an intermediate medium. It can refer to either internal communication between two components or the interaction between the two components. Ordinary technicians in this field can understand the specific meanings of the above-mentioned terms in the present invention based on specific circumstances.

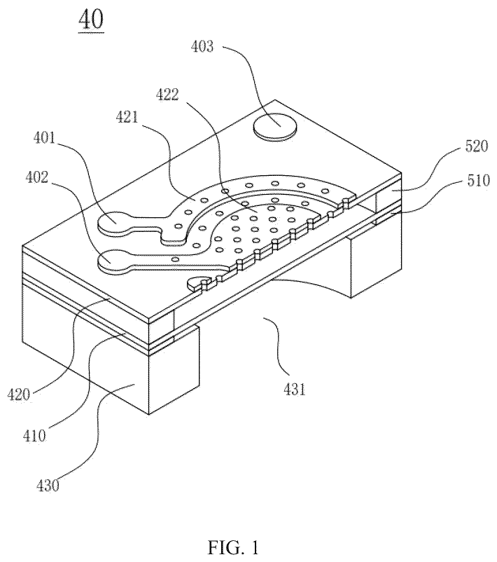

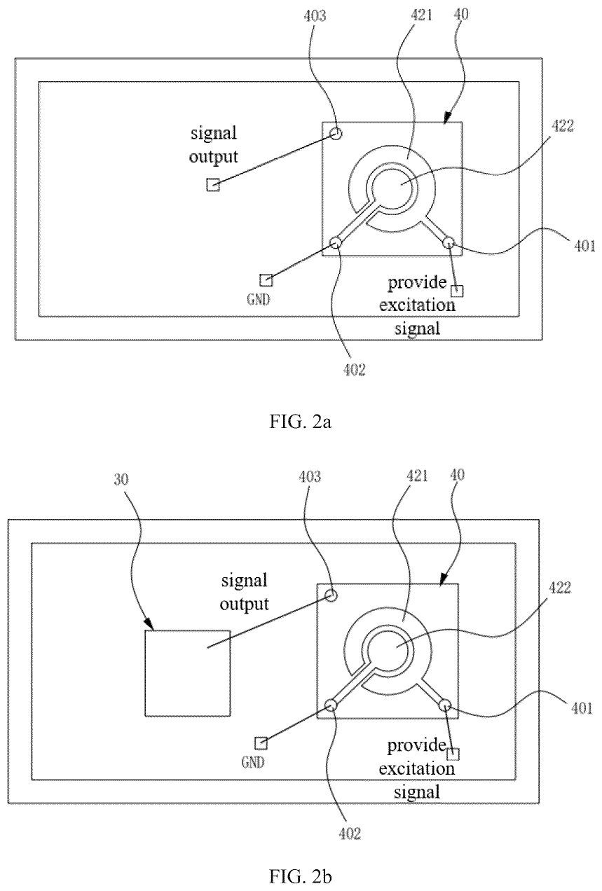

FIG. 1 is a schematic diagram of a structure of a MEMS chip 40 in a micro-differential pressure sensor, according to an embodiment of the present invention. FIG. 2A is a schematic diagram of a circuit structure of a MEMS chip 40 in a micro-differential pressure sensor, according to a first embodiment of the present invention.

As shown in FIG. 1 and FIG. 2a, according to a first aspect of the present invention, a micro-differential pressure sensor is provided. The micro-differential pressure sensor comprises a MEMS chip 40, the MEMS chip 40 comprises a substrate 430, a diaphragm 410, and a back-pole plate 420 set in a laminated manner. The substrate 430 having a back cavity 431 which passes through in the thickness direction thereof. The back-pole plate 420 comprises a first electrode region 421 and a second electrode region 422 isolated from each other. The first electrode region 421 forming a first electrode, the second electrode region 422 forming a second electrode, and the diaphragm 410 forming a third electrode. The first electrode and the third electrode form a first capacitor, and the second electrode and the third electrode form a second capacitor.

The MEMS chip 40 comprises a first electrical connection end 401, a second electrical connection end 402, and a third electrical connection end 403; wherein the first electrical connection end 401 is electrically connected to the first electrode. The first electrical connection end 401 is configured to provide a voltage excitation signal or a high voltage signal. The second electrical connection end 402 is electrically connected to the second electrode. The second electrical connection end 402 is configured to provide a ground signal. The third electrical connection end 403 is electrically connected to the third electrode. The third electrical connection end 403 serves as a signal output terminal of the MEMS chip 40 to output a change amount of the second capacitor, so as to determine whether the MEMS chip 40 is in a degraded state according to a first preset threshold.

It should be noted that in the embodiment of the present invention, when the MEMS chip 40 is in the degraded state. For example, the amount of change in the second capacitor output by the MEMS chip 40 is not within the range of the first preset threshold, the requirements of the design are not satisfied.

Adopting the technical solution provided in the embodiment of the present invention, by applying a voltage excitation signal or a high voltage signal or the like to the first electrode through the first electrical connection end 401, the diaphragm 410 is driven to deform to change the spacing between the diaphragm 410 and the back-pole plate 420 to simulate the airflow test method. Then, output the sensed signal through the third electrical connection end 403. The measured change amount of the second capacitor is used to determine whether the MEMS chip 40 is in the degraded state according to the first preset threshold. It can replace the existing art of the airflow test method for the MEMS chip 40 micro-differential pressure products, and have good test stability as well as high test efficiency.

In an embodiment of the present invention, if the first preset threshold is set too large, the diaphragm 410 may be affected due to the large amount of deformation of the diaphragm 410, and even the diaphragm 410 may be adhered to the back-pole plate 420. If the first preset threshold is set too small, the diaphragm 410's amount of deformation may be too small, making the MEMS chip 40 overly sensitive, causing a risk of false activation of the MEMS chip 40. Therefore, the range of the first preset threshold is configured as 1%-10% of the ratio of the change in the second capacitor to the total capacitance of the total signal link; wherein, the total capacitance of the total signal link is the sum of the capacitance of the MEMS chip 40, a parasitic capacitance of a circuit board electrically connected to the MEMS chip 40, and a reference capacitance of a detection chip. Within this range, it is possible to be compatible with the sensitivity of the MEMS chip 40 while preventing the diaphragm 410 from adhering, and also avoiding the risk of false triggering of the MEMS chip 40.

In some embodiments, applying a voltage excitation signal to the first electrode, to cause a change in the capacitance value of the first capacitor based on the change in the voltage excitation signal, and drive the diaphragm 410 to perform adsorption motion from the equilibrium position toward the side close to the back-pole plate 420 in an adsorption motion. At this time, the capacitance sensed by the second capacitor gradually becomes greater, and then, by detecting whether the amount of change in the second capacitor reaches the first preset threshold set by the micro-differential pressure sensor, it can be determined whether or not the MEMS chip 40 is in the degraded state.

In some other embodiments, when a stable high voltage signal is applied to the first electrode through the first electrical connection end 401. The gap between the diaphragm 410 and the back-pole plate 420 is instantaneously reduced based on the stable high voltage signal. Then, the value of the high voltage signal is gradually reduced, causing the diaphragm 410 to gradually pop open (for example, the diaphragm 410 returns to the equilibrium position from the deformed position). The distance between the diaphragm 410 and the back-pole plate 420 gradually becomes greater in the process of the diaphragm 410 popping open. In the process of the diaphragm 410 popping open, the spacing between the diaphragm 410 and the back-pole plate 420 is gradually increasing. At this time, the capacitance of the sensed second capacitor is gradually decreasing. By detecting whether the amount of change in the second capacitor reaches the first preset threshold set by the micro-differential pressure sensor, it can be determined whether or not the MEMS chip 40 is in the degraded state. In some embodiments, the range of the stable high voltage signal is 10V to 50V.

In an embodiment of the present invention, the back-pole plate 420 comprises an insulating layer (not shown in the figure) and an electrically conductive layer (not shown in the figure) fixedly connected to the insulating layer. The electrically conductive layer is disposed on a side of the insulating layer away from the diaphragm 410 in a thickness direction of the substrate 430. The electrically conductive layer comprises the first electrode region 421 and the second electrode region 422 isolated from each other. The first electrode region 421 forming the first electrode, and the second electrode region 422 forming the second electrode. A first support body 510 is further provided between the diaphragm 410 and the substrate 430 to support the diaphragm 410, and a second support body 520 is further provided between the diaphragm 410 and the back-pole plate 420 to support the back-pole plate 420. The first support body 510 and the second support body 520 are insulating support bodies. For example, the material of the first support body 510 and the second support body 520 can be silicon oxide, silicon nitride, or the like. The thickness of the first support body 510 and the second support body 520 is between 2 and 3 um. For example, the thickness of the first support body 510 and the second support body 520 is around 2.5 μm. In the embodiment of the present invention, the materials of the conductive layer of the diaphragm 410 and the back-pole plate 420 are both polysilicon.

In some embodiments, the first electrical connection end 401, the second electrical connection end 402, and the third electrical connection end 403 are disposed on a surface of the MEMS chip 40. Optionally, the first electrical connection end 401, the second electrical connection end 402, and the third electrical connection end 403 are formed by fabricating the conductive layer on the back-pole plate 420.

In some embodiments, an axial distance from any point on the first electrode region 421 to the geometric center of the diaphragm 410 is greater than an axial distance from any point on the second electrode region 422 to the geometric center of the diaphragm 410, with the geometric center passing through the diaphragm 410 being the axis.

In some embodiments, one of the first electrode region 421 and the second electrode region 422 is surrounded by the other.

In some embodiments, one of the first electrode region 421 and the second electrode region 422 comprises a first portion and a second portion, the first portion is surrounded by the second portion, and the second portion surrounds the first portion.

In some embodiments, the first electrode region 421 and the second electrode region 422 are concentrically disposed.

In some embodiments, The projections of both the first electrode region 421 and the second electrode region 422 are disposed within the projection of the vibration-sensitive region of the diaphragm 410.

FIG. 2B is a schematic diagram of a circuit structure in connecting the MEMS chip 40 and the ASIC chip 30 in the micro-differential pressure sensor, according to a second embodiment of the present invention.

As shown in FIG. 2B, the micro-differential pressure sensor further includes an ASIC (Application Specific Integrated Circuit) chip for signal amplification, at this time, the input of the ASIC chip 30 is electrically connected to the third electrical connection end 403 for detecting and analyzing the amount of change in the second capacitor.

According to a second aspect of the present invention, a micro-differential pressure sensor packaging structure 1000 is provided.

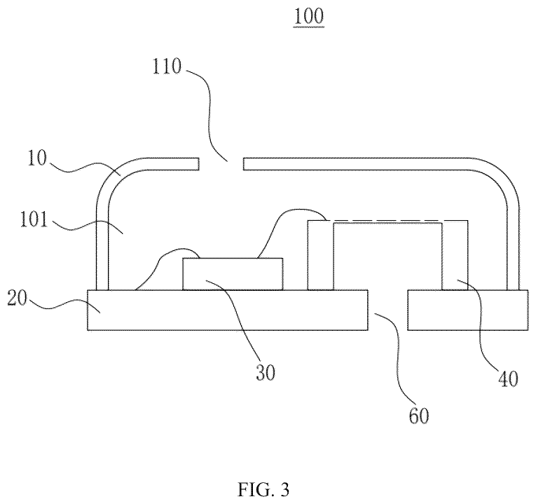

FIG. 3 is a schematic diagram of a side view structure of a micro-differential pressure sensor packaging structure 1000, according to an embodiment of the present invention.

As shown in FIG. 1-FIG. 3, the packaging structure 1000 comprises a baseplate 20, a housing 10, and the above-mentioned micro-differential pressure sensor. The baseplate 20 comprises a first surface 20A and a second surface 20B positioned opposite to each other. The first surface 20A of the baseplate 20 is fixedly connected to the housing 10 to form a cavity 101. The MEMS chip 40 is fixedly connected to the first surface 20A and disposed in the cavity 101. a first through hole 60 is formed on the baseplate 20, and the MEMS chip 40 covers the first through hole 60. The first surface 20A comprises a first signal terminal 201201, a ground terminal 202, and a second signal terminal 203 spaced apart; wherein the first signal terminal 201 is configured to be electrically connected to the first electrical connection end 401, the ground terminal 202 is configured to be electrically connected to the second electrical connection end 402, and the second signal terminal 203 is configured to be electrically connected to the third electrical connection end 403.

In an embodiment of the present invention, the baseplate 20 is a PCB (Printed Circuit Board), and the PCB is a support for electronic components (e.g., MEMS devices and ASIC devices), and a carrier for electrically interconnecting the electronic components. For instance, the PCB undergoes copper trace design to act as interconnecting wires.

In an embodiment of the present invention, the housing 10 is a metal housing 10, also referred to as a shielding housing 10, wherein the metal housing 10 is fixed to the baseplate 20 to form a cavity 101 for shielding from external electromagnetic field interference.

In an embodiment of the present invention, the packaging structure 1000 also comprises a first air permeable structure 110. After bonding and fixing the housing 10 to the baseplate 20, one side surface of the MEMS chip 40 is connected to the first through hole 60, and the other side surface of the MEMS chip 40 is connected to the space outside of the packaging structure 1000 through the location of the first air permeable structure 110. So that the MEMS chip 40 is capable of sensing the signal of the pressure difference between the first through hole 60 and the first air permeable structure 110.

In an embodiment of the present invention, the packaging structure 1000 also comprises a first air permeable structure 110, and after bonding and fixing the housing 10 to the baseplate 20. One side surface of the MEMS chip 40 is connected to the first through hole 60. The other side surface of the MEMS chip 40 is connected to the space outside of the packaging structure 1000 through the location of the first air permeable structure 110. So that the MEMS chip 40 is capable of sensing the signal of the pressure difference between the first through hole 60 and the first air permeable structure 110.

In the embodiment shown in FIG. 3, the ASIC chip 30 is also disposed within the cavity 101 and secured to the first surface 20A of the baseplate 20. It should be understood that in some other embodiments, the ASIC chip 30 may also be disposed outside the cavity 101, for example, outside the housing 10. The embodiments of the present invention are not limited herein.

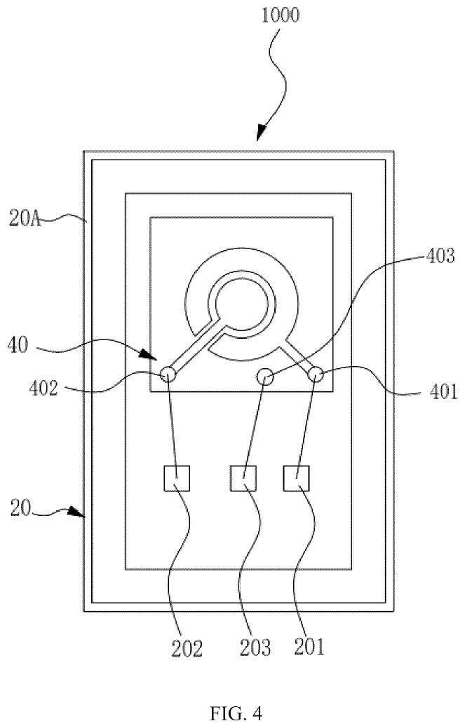

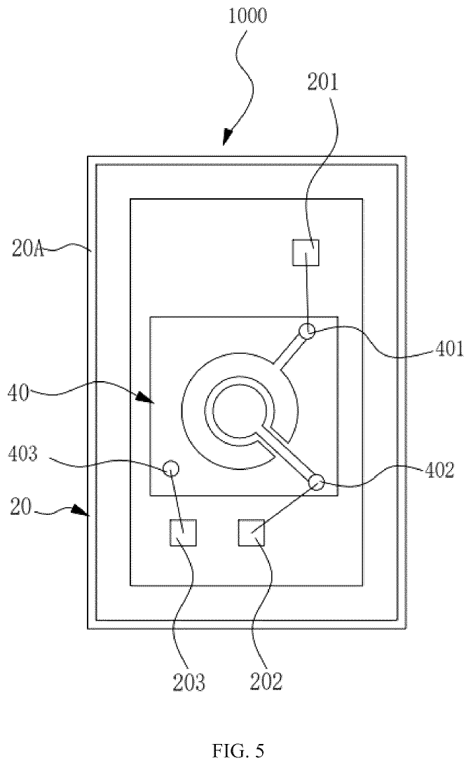

FIG. 4 is a schematic diagram of a top view structure of a micro-differential pressure sensor packaging structure 1000, according to a first embodiment of the present invention.

In the embodiment as shown in FIG. 4, the packaging structure 1000 comprises only a MEMS chip 40 for pressure conversion to detect capacitive signals only as an gas flow sensor. The first signal terminal 201, the ground terminal 202 and the second signal terminal 203 are disposed on one side of the MEMS chip 40.

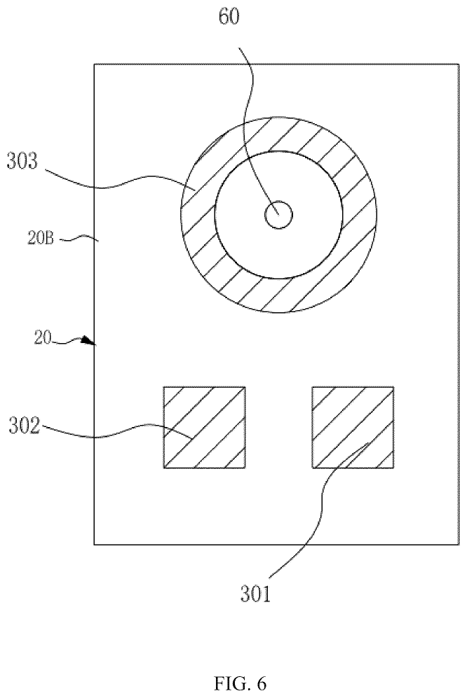

In the embodiment as shown in FIG. 6-FIG. 12, in order to be applicable to SMT (Surface Mounted Technology), a second surface 20B (i.e., the surface on the side backing away from the housing 10) of the baseplate 20 is provided with a first pad 301, a ground pad 302, and a second pad 303 for electrically connecting to the pre-fabricated wiring board, and the first pad 301, the ground pad 302, and the second pad 303 are spaced apart from each other; wherein the first pad 301 is configured to be electrically connected to the first signal terminal 201; the ground pad 302 is configured to be electrically connected to the ground terminal 202; and the second pad 303 is configured to be electrically connected to the second signal terminal 203.

After the micro-differential pressure sensor packaging structure 1000 is attached to the corresponding area of the preset circuit board, in order to enhance the sealing around the first through-hole of the packaging structure 1000, in some embodiments, as shown in FIG. 6, the second pad 303 is annular and disposed surrounding the first through hole 60, the ground pad 302 and the first pad 301 are both block-shaped, and the ground pad 302 and the first pad 301 are both disposed on a side of the second pad 303 away from the first through hole 60.

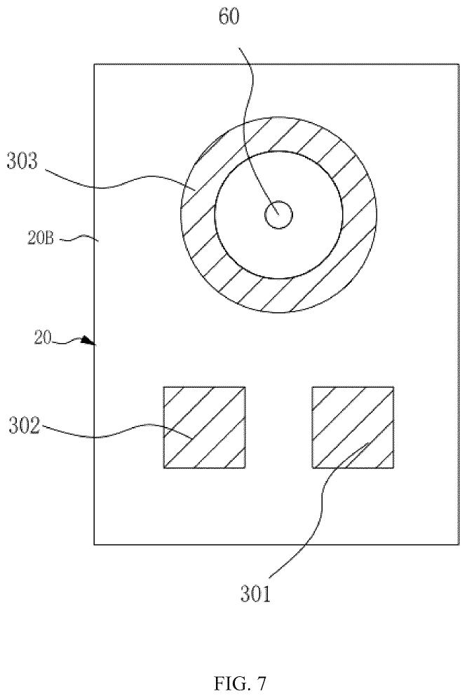

In some embodiments, as shown in FIG. 7, the second pad 303 is annular, the ground pad 302 and the first pad 301 are both block-shaped, and the ground pad 302, the first pad 301, and the first through hole 60 are surrounded by the second pad 303.

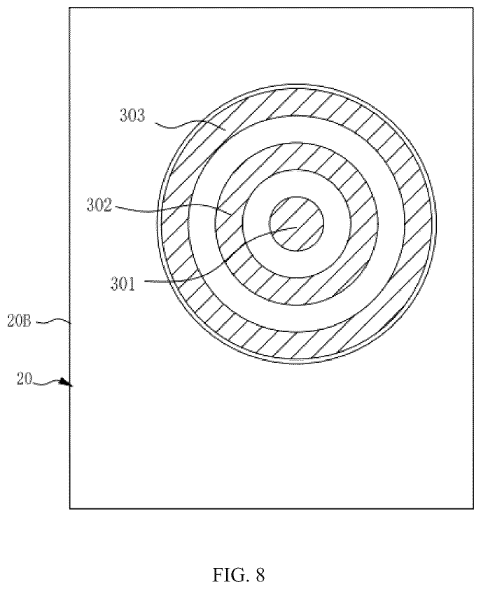

In some embodiments, as shown in FIG. 8, the first pad 301, the ground pad 302, and the second pad 303 are annular; the second pad 303 surrounds the ground pad 302, and the ground pad 302 surrounds the first pad 301. When the micro-differential pressure sensor packaging structure 1000 is applied to the electronic cigarette product for use as a switch for activating the electronic cigarette, the use of the height difference between each of the first pad 301, the ground pad 302, and the second pad 303 and the second surface 20B of the baseplate 20 to height difference, a retaining wall structure is formed. The retaining wall structure can effectively solve the problem of polarity short-circuit between pads with different polarities due to oil leakage in the electronic cigarette product.

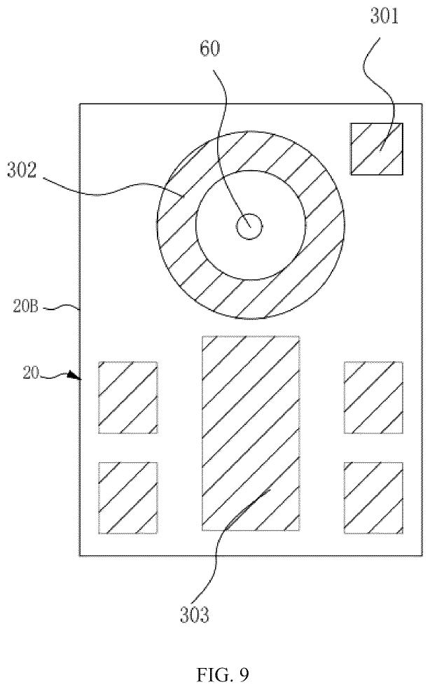

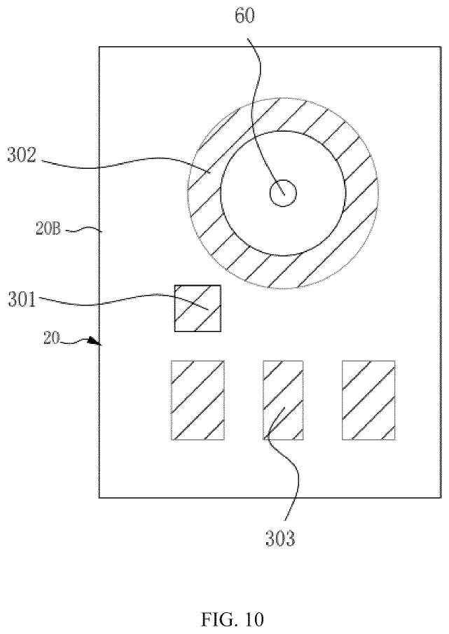

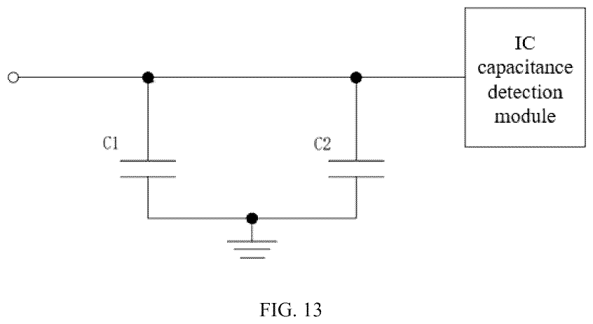

In some embodiments, as shown in FIG. 9 or FIG. 10, the ground pad 302 is annular and is disposed surrounding the first through hole 60; the first pad 301 is block-shaped, and the first pad 301 is disposed on a side of the ground pad 302 away from the first through hole 60. When testing the micro-differential pressure sensor, a voltage excitation signal or a stable high voltage signal may be applied to the first pad 301 alone, and the electrical signal output from the second pad 303 may be detected. In practical application, the first pad 301 and the ground pad 302 can be shorted in a preset manner, for example, by shorting the first pad 301 to the ground pad 302 through a metal lead to enable the first capacitor and the second capacitor to be connected in parallel. Thereby, the IC (Integrated Circuit) capacitance detection module detects the capacitance value of the first capacitor C1 and the second capacitor C2 in parallel as shown in FIG. 13, and thus effectively enhances the sensitivity of the MEMS chip 40.

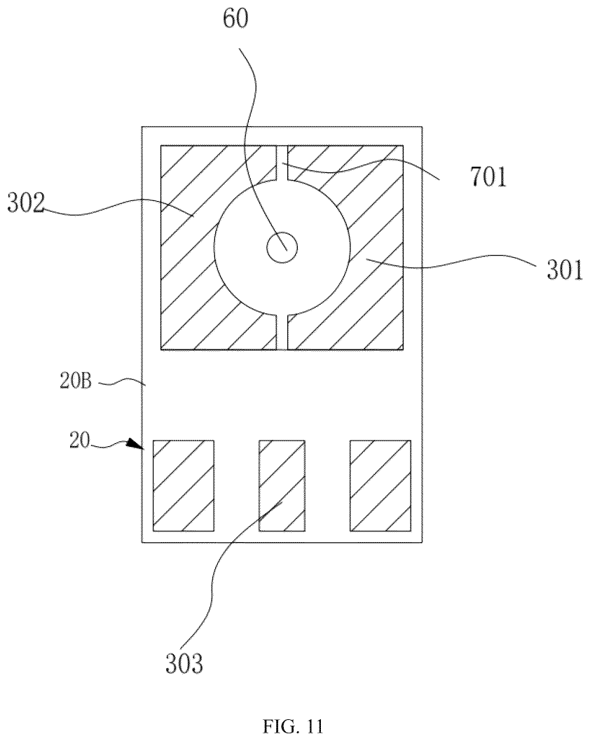

In some embodiments, in order to facilitate easier realization of shorting the first pad 301 to the ground pad 302 in actual use, as shown in FIG. 11, the ground pad 302 and the first pad 301 are in a disconnected annular state, and both the ground pad 302 and the first pad 301 are disposed surrounding the first through hole 60. The annular disconnected annular part is an insulating part.

In this embodiment, the ground pad 302 and the first pad 301 with different polarities are enclosed to form a ring-shaped pad structure. In testing applications, a voltage excitation signal or a stable high voltage signal is individually applied to the first pad 301, and an electrical signal reflecting the amount of change in the second capacitor is tested on the second pad 303 to determine whether the MEMS chip 40 is in the degraded state. In practice, a corresponding electrically conductive connection pattern layer is fabricated on a preset circuit board. Then, a solder is applied to the electrically connected pattern layer. By using conductive material (such as solder paste shorting) in the solder to create a short circuit, shorting of the ground pad 302 to the first pad 301 is realized. Thereby, the capacitance value of the first capacitor C1 and the second capacitor C2 after parallel connection can be obtained as shown in FIG. 13.

In a further example, the outer contour of the planar pattern formed by the ground pad 302 and the first pad 301 is polygonal, so as to increase the effective area of the electrical connection with the preset circuit board. Accordingly, the sealing performance around the first through hole 60 of the packaging structure 1000 is improved, and the reliability of the electrical connection between the packaging structure 1000 and the preset circuit board is enhanced.

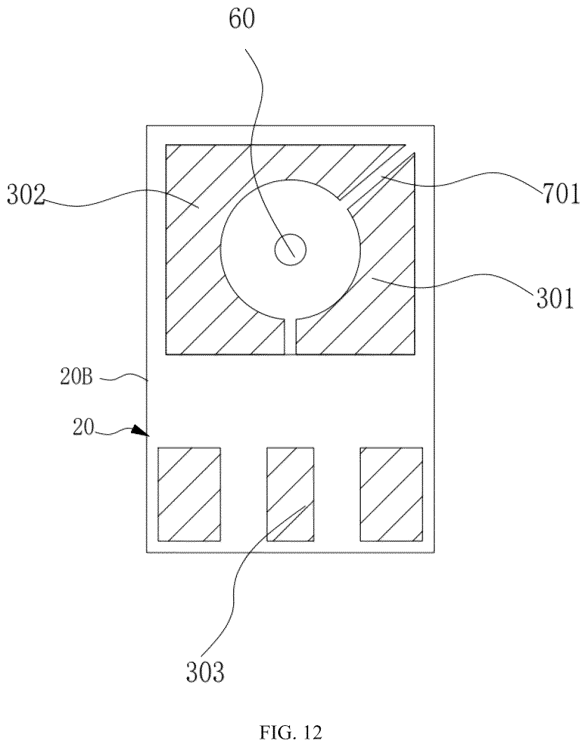

In a further example, as shown in FIG. 12, the ground pad 302 and the first pad 301 have an isolation band 701 with a spacing distance less than or equal to a preset value therebetween, and an extension path of the isolation band 701 passes through one of the corners of the polygon. By extending the length of the isolation band 701, the gap between the ground pad 302 and the first pad 301 can thus be better blocked by the conductive material in the solder to achieve the sealing, as well as to enhance the reliability of the shorting.

As an illustration, in the embodiment of FIG. 6-FIG. 8 above, in practical application, instead of shorting the ground pad 302 and the first pad 301, only the second capacitor can be used as the sensing capacitance of the MEMS chip 40. The sensitivity of the MEMS chip 40 can be adjusted by the amount of capacitance change of this second capacitor.

According to a third aspect of the present invention, a testing method is provided. The testing method is used to test the above-mentioned micro-differential pressure sensor, or is used to test the above-mentioned packaging structure 1000, wherein the testing method comprises the steps of:

Step S1, applying a voltage excitation signal to the first electrode, to cause a change in the capacitance value of the first capacitor based on the change in the voltage excitation signal, and drive the diaphragm 410 to perform adsorption moption from an equilibrium position toward the side close to the back-pole plate 420 in an adsorption motion; or, applying a high voltage signal to the first electrode, to cause the diaphragm 410 to deform based on the high voltage signal, and then gradually reduce the high voltage signal, so as to cause the diaphragm 410 to return from the deformed position to the equilibrium position.

Step S2, obtaining the change amount of the second capacitor, and determine whether the change amount of the second capacitor reaches the first preset threshold. If so, determine the MEMS chip 40 to be in a non-degraded state; otherwise, determine the MEMS chip 40 to be in a degraded state.

In some embodiments, in step S1, utilizing a voltage excitation signal applied to the first electrode, and based on the change of the voltage excitation signal, causing the capacitance value of the first capacitor to change from a low value to a high value. The diaphragm 410 is driven to make the adsorption motion from the equilibrium position toward the side close to the back-pole plate 420. In this case, the capacitance sensed by the second capacitor gradually becomes greater. Further, by detecting whether the amount of change in the second capacitor reaches the first preset threshold set by the micro-differential pressure sensor, it can be determined whether the MEMS chip 40 is in the degraded state. It is applicable to activate the IC detection module by detecting the change in the detected capacitance to become larger.

In some other embodiments, a stable high voltage signal, such as a high voltage signal of 20V to 50V, is first applied to the first electrode, causing the gap between the diaphragm 410 and the back-pole plate 420 to instantly decrease. Then, the value of the high voltage signal is gradually reduced, causing the diaphragm 410 to gradually pop open. In the process of diaphragm 410 popping open, the distance between the diaphragm 410 and the back-pole plate 420 is gradually getting greater. At this time, the capacitance of the second capacitor sensed by the MEMS chip 40 gradually decreases, and then it can be determined whether the MEMS chip 40 is in the degraded state by detecting whether or not the amount of change in the second capacitor reaches the first preset threshold set by the micro-differential pressure sensor. It is applicable for the detected capacitance to become decreased to activate the IC detection module. Both of the above embodiments are covered by the present invention.

The present invention also provides an electronic device, the electronic device comprising the above-mentioned packaging structure 1000. The electronic device comprises a microphone, an electronic cigarette, or the like. Therefore, embodiments of the present invention provide a micro-differential pressure sensor, a packaging structure 1000, a test method, and an electronic device that can replace the existing art of the airflow test method for the MEMS chip 40 micro-differential pressure products, and have good test stability as well as high test efficiency.

The micro-differential pressure sensor comprises a MEMS chip 40, the MEMS chip 40 comprises a substrate 430, a diaphragm 410, and a back-pole plate 420 set in a laminated manner, the substrate 430 having a back cavity 431 which passes through in the thickness direction thereof, the back-pole plate 420 comprises a first electrode region 421 and a second electrode region 422 isolated from each other, the first electrode region 421 forming a first electrode, the second electrode region 422 forming a second electrode, and the diaphragm 410 forming a third electrode, the first electrode and the third electrode form a first capacitor, and the second electrode and the third electrode form a second capacitor.

By applying a voltage excitation signal or a high voltage signal or the like to the first electrode through the first electrical connection end 401, the diaphragm 410 is driven to deform to change the spacing between the diaphragm 410 and the back-pole plate 420 to simulate the airflow test method; and then output the sensed signal through the third electrical connection end 403. The measured change amount of the second capacitor is used to determine whether the MEMS chip 40 is in the degraded state according to the first preset threshold.

In some embodiments, the range of the first preset threshold is configured as 1%-10% of the ratio of the change in the second capacitor to the total capacitance of the total signal link; wherein the total capacitance of the total signal link is the sum of the capacitance of the MEMS chip, a parasitic capacitance of a circuit board electrically connected to the MEMS chip, and a reference capacitance of a detection chip.

In some embodiments, the first electrical connection end, the second electrical connection end, and the third electrical connection end are disposed on a surface of the MEMS chip.

In some embodiments, an axial distance from any point on the first electrode region to the geometric center of the diaphragm is greater than an axial distance from any point on the second electrode region to the geometric center of the diaphragm, with the geometric center passing through the diaphragm being the axis.

In some embodiments, one of the first electrode region and the second electrode region is surrounded by the other.

In some embodiments, one of the first electrode region and the second electrode region comprises a first portion and a second portion, the first portion is surrounded by the second portion, and the second portion surrounds the first portion.

In some embodiments, the first electrode region and the second electrode region are concentrically disposed.

In some embodiments, the micro-differential pressure sensor further comprises an ASIC (Application Specific Integrated Circuit) chip for signal amplification, and an input end of the ASIC chip is electrically connected to the third electrical connection end.

In some embodiments, the second surface comprises a first pad, a ground pad and a second pad spaced apart;
wherein the first pad is configured to be electrically connected to the first signal terminal; the ground pad is configured to be electrically connected to the ground terminal; and the second pad is configured to be electrically connected to the second signal terminal.

In some embodiments, the second pad is annular and disposed surrounding the first through hole,
the ground pad and the first pad are both block-shaped, and the ground pad and the first pad are both disposed on a side of the second pad away from the first through hole.

In some embodiments, the second pad is annular,
the ground pad and the first pad are both block-shaped, and the ground pad, the first pad, and the first through hole are surrounded by the second pad.

In some embodiments, the first pad, the ground pad, and the second pad are annular;
the second pad surrounds the ground pad, and the ground pad surrounds the first pad.

In some embodiments, the ground pad is annular and is disposed surrounding the first through hole;
the first pad is block-shaped, and the first pad is disposed on a side of the ground pad away from the first through hole.

In some embodiments, the ground pad and the first pad are in a disconnected annular state, and both the ground pad and the first pad are disposed surrounding the first through hole, and the annular disconnected annular part is an insulating part.

In some embodiments, the outer contour of the planar pattern formed by the ground pad and the first pad is polygonal.

In some embodiments, the ground pad and the first pad have an isolation band with a spacing distance less than or equal to a preset value therebetween, and an extension path of the isolation band passes through one of the corners of the polygon.

In some embodiments, the ground pad and the first pad are short-circuited in a preset manner such that the first capacitor and the second capacitor to be connected in parallel.

The above embodiments are intended to illustrate the technical solution of this application rather than limiting it. Although detailed descriptions have been provided with reference to the aforementioned embodiments, those skilled in the art should understand that modifications can still be made to the technical solutions described in the aforementioned embodiments, or equivalent substitutions can be made for some technical features. Such modifications or substitutions should not depart from the essence, spirit, and scope of the technical solutions of the embodiments of the present invention.

1. A micro-differential pressure sensor, wherein the micro-differential pressure sensor comprises a MEMS chip (40), the MEMS chip (40) comprises a substrate (430), a diaphragm (410), and a back-pole plate (420) set in a laminated manner, the substrate (430) having a back cavity (431) which passes through the substrate (430) in the thickness direction thereof, the back-pole plate (420) comprises a first electrode region (421) and a second electrode region (422) isolated from each other, the first electrode region (421) forming a first electrode, the second electrode region (422) forming a second electrode, and the diaphragm (410) forming a third electrode, the first electrode and the third electrode form a first capacitor, and the second electrode and the third electrode form a second capacitor;
the MEMS chip (40) comprises a first electrical connection end (401), a second electrical connection end (402), and a third electrical connection end (403);
wherein the first electrical connection end (401) is electrically connected to the first electrode, the first electrical connection end (401) being configured to provide a voltage excitation signal or a high voltage signal to make the diaphragm deformed, so as to change the distance between the diaphragm and the back-pole plate; the second electrical connection end (402) is electrically connected to the second electrode, the second electrical connection end (402) being configured to provide a ground signal; the third electrical connection end (403) is electrically connected to the third electrode, and the third electrical connection end (403) serves as a signal output terminal of the MEMS chip (40) to output a change amount of the second capacitor, so as to determine whether the MEMS chip (40) is in a degraded state according to a first preset threshold.

2. The micro-differential pressure sensor according to claim 1, wherein the range of the first preset threshold is configured as 1%-10% of the ratio of the change in the second capacitor to the total capacitance of the total signal link;
wherein the total capacitance of the total signal link is the sum of the capacitance of the MEMS chip (40), a parasitic capacitance of a circuit board electrically connected to the MEMS chip (40), and a reference capacitance of a detection chip.

3. The micro-differential pressure sensor according to claim 1, wherein the first electrical connection end (401), the second electrical connection end (402), and the third electrical connection end (403) are disposed on a surface of the MEMS chip (40).

4. The micro-differential pressure sensor according to claim 1, wherein an axial distance from any point on the first electrode region (421) to the geometric center of the diaphragm (410) is greater than an axial distance from any point on the second electrode region (422) to the geometric center of the diaphragm (410), with the geometric center passing through the diaphragm (410) being the axis.

5. The micro-differential pressure sensor according to claim 4, wherein one of the first electrode region (421) and the second electrode region (422) is surrounded by the other.

6. The micro-differential pressure sensor according to claim 4, wherein one of the first electrode region (421) and the second electrode region (422) comprises a first portion and a second portion, the first portion is surrounded by the second portion, the second portion surrounds the first portion.

7. The micro-differential pressure sensor according to claim 4, wherein the first electrode region (421) and the second electrode region (422) are concentrically disposed.

8. The micro-differential pressure sensor according to claim 1, wherein the micro-differential pressure sensor further comprises an ASIC chip (30) for signal amplification, and an input end of the ASIC chip (30) is electrically connected to the third electrical connection end (403).

9. A micro-differential pressure sensor packaging structure, wherein the packaging structure comprises a baseplate (20), a housing (10), and the micro-differential pressure sensor according to claim 1;
the baseplate (20) comprises a first surface (20A) and a second surface (20B) positioned opposite to each other, the first surface (20A) of the baseplate (20) is fixedly connected to the housing (10) to form a cavity (101), the MEMS chip (40) is fixedly connected to the first surface (20A) and disposed in the cavity (101), a first through hole (60) is formed on the baseplate (20), and the MEMS chip (40) covers the first through hole (60);
the first surface (20A) comprises a first signal terminal (201), a ground terminal (202), and a second signal terminal (203) spaced apart;
wherein the first signal terminal (201) is configured to be electrically connected to the first electrical connection end (401), the ground terminal (202) is configured to be electrically connected to the second electrical connection end (402), and the second signal terminal (203) is configured to be electrically connected to the third electrical connection end (403).

10. The packaging structure according to claim 9, wherein the second surface (20B) comprises a first pad (301), a ground pad (302) and a second pad (303) spaced apart;
wherein the first pad (301) is configured to be electrically connected to the first signal terminal (201); the ground pad (302) is configured to be electrically connected to the ground terminal (202); and the second pad (303) is configured to be electrically connected to the second signal terminal (203).

11. The packaging structure according to claim 10, wherein the second pad (303) is annular and disposed surrounding the first through hole (60);
the ground pad (302) and the first pad (301) are both block-shaped, and the ground pad (302) and the first pad (301) are both disposed on a side of the second pad (303) away from the first through hole (60).

12. The packaging structure according to claim 10, wherein the second pad (303) is annular;
the ground pad (302) and the first pad (301) are both block-shaped, and the ground pad (302), the first pad (301), and the first through hole (60) are surrounded by the second pad (303).

13. The packaging structure according to claim 10, wherein the first pad (301), the ground pad (302), and the second pad (303) are annular;
the second pad (303) surrounds the ground pad (302), and the ground pad (302) surrounds the first pad (301).

14. The packaging structure according to claim 10, wherein the ground pad (302) is annular and is disposed surrounding the first through hole (60);
the first pad (301) is block-shaped, and the first pad (301) is disposed on a side of the ground pad (302) away from the first through hole (60).

15. The packaging structure according to claim 10, wherein the ground pad (302) and the first pad (301) are in a disconnected annular state, and both the ground pad (302) and the first pad (301) are disposed surrounding the first through hole (60), and the disconnected annular part is an insulating part.

16. The packaging structure according to claim 15, wherein the outer contour of the planar pattern formed by the ground pad (302) and the first pad (301) is polygonal.

17. The packaging structure according to claim 16, wherein the ground pad (302) and the first pad (301) have an isolation band (701) with a spacing distance less than or equal to a preset value therebetween, and an extension path of the isolation band (701) passes through one of the corners of the polygon.

18. The packaging structure according to claim 16, wherein the ground pad (302) and the first pad (301) are short-circuited in a preset manner such that the first capacitor and the second capacitor are connected in parallel.

19. A testing method, for testing the micro-differential pressure sensor according to claim 1, wherein the testing method comprises the steps of:
applying a voltage excitation signal to the first electrode, to cause a change in the capacitance value of the first capacitor based on the change in the voltage excitation signal, and drive the diaphragm (410) to perform adsorption motion from an equilibrium position toward the side close to the back-pole plate (420); or, applying a high voltage signal to the first electrode, to cause the diaphragm (410) to deform based on the high voltage signal, and then gradually reduce the high voltage signal, so as to cause the diaphragm (410) to return from the deformed position to the equilibrium position;
obtaining the change amount of the second capacitor, and determine whether the change amount of the second capacitor reaches the first preset threshold, if so, determine the MEMS chip (40) to be in a non-degraded state; otherwise, determine the MEMS chip (40) to be in a degraded state.

20. An electronic device, wherein the electronic device comprises the packaging structure according to claim 9.

21. A testing method, for testing the packaging structure according to claim 9, wherein the testing method comprises the steps of:
applying a voltage excitation signal to the first electrode, to cause a change in the capacitance value of the first capacitor based on the change in the voltage excitation signal, and drive the diaphragm (410) to perform adsorption motion from an equilibrium position toward the side close to the back-pole plate (420); or, applying a high voltage signal to the first electrode, to cause the diaphragm (410) to deform based on the high voltage signal, and then gradually reduce the high voltage signal, so as to cause the diaphragm (410) to return from the deformed position to the equilibrium position;
obtaining the change amount of the second capacitor, and determine whether the change amount of the second capacitor reaches the first preset threshold, if so, determine the MEMS chip (40) to be in a non-degraded state; otherwise, determine the MEMS chip (40) to be in a degraded state.
